(19) United States
(12) Patent Application Publication
(10) Pub. No.: US 2024/0184940 A1
(43) Pub. Date: Jun. 6, 2024

(54) DIGITAL TWIN DATA MODEL DRIVEN HIGH-PERFORMANCE VIRTUAL SIMULATION METHOD AND SYSTEM

(71) Applicant: SHANDONG UNIVERSITY, Jinan (CN)

(72) Inventors: Tianliang HU, Jinan (CN); Lili DONG, Jinan (CN); Songhua MA, Jinan (CN); Lin LV, Jinan (CN); Fei TAO, Jinan (CN)

(73) Assignee: SHANDONG UNIVERSITY, Jinan (CN)

(21) Appl. No.: 18/441,152

(22) Filed: Feb. 14, 2024

Related U.S. Application Data
(63) Continuation of application No. PCT/CN2023/081712, filed on Mar. 15, 2023.

(30) Foreign Application Priority Data
Oct. 18, 2022 (CN) 2022112722624

(51) Int. Cl. G06F 30/17

(52) U.S. Cl. CPC G06F 30/17

(57) ABSTRACT

A digital twin data model driven high-performance virtual simulation method and system, including: based on a product design process, paying attention to variable operating conditions or variable product structures to obtain three kinds of data relevant to a design product, relevant products, or operating conditions: sensor data, mechanism simulation data, and fusion data obtained by correcting the mechanism simulation data with the sensor data; processing the obtained data, reversely resolving a running mechanism according to a data driven algorithm, and building a data model driven high-performance virtual simulation model; and based on new operating conditions of the design product or improved new products, calling the built data model driven high-performance virtual simulation model to obtain the virtual simulation results. The method and system can be used for performance analysis and prediction on design products instead of modeling simulation and physical experiments.

The present invention claims the priority of the Chinese Patent Application 202211272262.4 filed to the China National Intellectual Property Administration on Oct. 18, 2022, and entitled “DIGITAL TWIN DATA MODEL DRIVEN HIGH-PERFORMANCE VIRTUAL SIMULATION METHOD AND SYSTEM”, which is incorporated herein by reference in its entirety.

### TECHNICAL FIELD

The present invention belongs to the technical field of industrial equipment intelligentization and digitization, and in particular to a digital twin data model driven high-performance virtual simulation method and system.

### BACKGROUND

The description in this section merely provides background information related to the present invention and does not necessarily constitute the related art.

As is well-known, in order to verify the performance of new products during design, formation, and optimization and improvement stages, it is necessary to perform product validation experiments by simulating product running environment. However, physical experiments have high verification cost and time cost. Particularly for product design with complicated structures and complicated operating conditions, accurate simulation of the real product running condition through sample piece physical tests for conducting performance evaluation is limited by economic and manual experiment cost sometimes, and has poor implementation. In recent years, with the development of numerical simulation and computer performance, a computer simulation technology has become an effective tool for performing experiment verification instead of sample piece physical experiments.

At present, according to a method adopted by the computer simulation technology, product physical experiment conditions are simulated by using simulation software, and product performance characterization virtual simulation results are obtained through digital simulation, and are used for evaluating/verifying the product performance. However, the requirement on the computer performance is high in the whole process of a conventional digital simulation method, and simulation solution periods are long. Particularly, during the product iterative optimization design and analysis on the product performance under continuous running conditions, the simulation calculation is complicated, the duration of the simulation period is generally very long and is difficult to estimate, and such a condition occurs even in a high-performance computer cluster. At present, a method for solving the above problem is to build reduced-order models to shorten the simulation solution time by reducing the dimension of the state space model. However, the solution time reduction by the method is limited, the precision loss is difficult to control, and moreover, the method is not applicable to all simulation software. Additionally, during the product iterative optimization design and analysis of the design product performance under continuous running conditions, the problem of long simulation period of the performance verification evaluation cannot be still fundamentally solved.

With the development of a new generation of information technology, an effective method is provided for the product virtual performance verification through the appearance of a digital twin (DT) concept. The DT is considered as an effective enabling measure for realizing cyber-physical fusion, and is considered as a simulation technology integrating multiple-disciplinary, multiple-physical quantity, multiple-scale, and multiple-probability, and digital system implementation factors include three parts: a mechanism model, a data model, and an algorithm model. Through the DT technology, reliable data information may be obtained from product DT models or a physical space, and the application algorithm model is used, which provides the possibility for carrying out product design performance verification.

Based on the above, how to utilize the DT technology to fast obtain the virtual experiment data similar to the digital simulation or physical simulation experiment/running experiment during the product design stage, realize product performance prediction and analysis, and accelerate the product forward design and iteration is a challenge for performing virtual experiment verification at present.

### SUMMARY

In order to overcome the defects in the related art, the present invention provides a DT data model driven high-performance virtual simulation method and system. The method and system are applicable to two situations, including product iterative optimization design and performance analysis of the design product under continuous running conditions. Mechanism models of relevant products/design product are built by using a DT technology. One or more of the mechanism simulation data, running monitoring data or physical experiment simulation data and fusion data that characterize product performance are obtained. Then, a single data or fusion data driven high-performance virtual simulation model is built for a simulation requirement. Product mechanism models are reversely resolved according to a data driven algorithm, so as to achieve running mechanism simulation and performance evaluation of the physical space required by the same type of design products or design under different operating conditions, replacing modeling simulation or physical experiments, conducting design product performance analysis and prediction, and shortening the time for design product performance verification.

In order to achieve the above objective, one or more embodiments of the present invention provide the following technical solutions:

In a first aspect, the present invention provides a DT data model driven high-performance virtual simulation method.

The DT data model driven high-performance virtual simulation method includes:
based on a product design process, paying attention to variable operating conditions or variable product structures to obtain three kinds of data relevant to a design product, relevant products, or operating conditions: sensor data, mechanism simulation data, and fusion data obtained by correcting the mechanism simulation data with the sensor data;
processing the obtained data, reversely resolving the running mechanism according to the data driven algorithm, and building a data model driven high-performance virtual simulation model;
based on new operating conditions of the design product or improved new products, calling the built data model driven high-performance virtual simulation model to obtain virtual simulation results; and
analyzing performance of design product under new operating conditions or new products according to the virtual simulation results to provide feedback guidance for product design.

In a second aspect, the present invention provides a DT data model driven high-performance virtual simulation system.

The DT data model driven high-performance virtual simulation system includes:
a data obtaining module, configured to: based on a product design process, pay attention to variable operating conditions or variable product structures to obtain three kinds of data relevant to a design product, relevant products, or operating conditions: sensor data, mechanism simulation data, and fusion data obtained by correcting the mechanism simulation data with the sensor data;
a model building module, configured to: process the obtained data, reversely analyze the running mechanism according to the data driven algorithm, and build a data model driven high-performance virtual simulation model;
a virtual simulation result obtaining module, configured to: based on new operating conditions of the design product or improved new products, call the built data model driven high-performance virtual simulation model to obtain virtual simulation results; and
a feedback guidance module, configured to: analyze performance of design product under new operating conditions or new products according to the virtual simulation results to provide feedback guidance for product design.

In a third aspect, the present invention provides a computer-readable storage medium, storing a program. The program implements the steps of the DT data model driven high-performance virtual simulation method according to the first aspect of the present invention when being executed by a processor.

In a fourth aspect, the present invention provides an electronic device, including a memory, a processor, and a program stored on the memory and capable of running on the processor. The processor implements the steps of the DT data model driven high-performance virtual simulation method according to the first aspect of the present invention when executing the program.

The above one or more technical solutions have the following beneficial effects:

The present invention utilizes the DT technology, builds design or relevant product mechanism models and data model driven high-performance virtual simulation model, obtains simulation data, sensor data and fusion data, performs digital simulation solution for new products or new operating conditions from a data driven aspect to obtain the running mechanism and perform performance evaluation, thereby solving the problems of high cost of the physical experiment and long solution time of computer simulation, and favoring accelerating the product forward performance verification.

The present invention utilizes the DT technology, obtains use process sensor data, physical experiment sensor data, or simulation data of multi-field DT mechanism models of the design product under discrete operating conditions or fusion data of the above data that characterize product performance for the discrete operating conditions of the design product, drives the high-performance virtual simulation model to analyze the physical space running mechanism and digital simulation running mechanism of the design product under the discrete operating conditions, and analyzes the performance of the design product under continuous operating conditions.

The present invention utilizes the DT technology, obtains the use process sensor data, physical experiment sensor data or simulation data of multi-field DT mechanism models of relevant products under the same operating condition or the fusion data of the above data that characterize product performance for the variable product structures of the same operating condition, drives the high-performance virtual simulation model to analyze the physical space running mechanism and digital simulation running mechanism of the relevant products under the same operating condition, and promotes the optimization iteration design of the design product.

The present invention utilizes one or more of three kinds of data including the simulation data, the sensor data and the fusion data to build the data model driven high-performance virtual simulation model, which can replace modeling simulation or physical experiment for performance analysis and prediction of the design product, so that the product performance verification time is shortened, and the product forward design and iteration is accelerated.

The advantages in additional aspects of the present invention will be set forth in part in the description below, parts of which will become apparent from the description below, or will be understood by the practice of the present invention.

### BRIEF DESCRIPTION OF THE DRAWINGS

The accompanying drawings constituting a part of the present invention are used to provide a further understanding of the present invention. The exemplary examples of the present invention and descriptions thereof are used to explain the present invention, and do not constitute an improper limitation of the present invention.

FIG. 1 is a flowchart of a method according to Embodiment 1 of the present invention.

FIG. 2 is a flowchart of a building process of multi-field DT models according to Embodiment 1 of the present invention.

FIG. 3 is a flowchart of a process of correcting simulation data by using sensor data according to Embodiment 1 of the present invention.

FIG. 4 is a flowchart showing a building process of a DT data model driven high-performance virtual simulation system according to Embodiment 1 of the present invention.

FIG. 5 is a flowchart of virtual simulation (performance verification prediction and analysis) of a design product according to Embodiment 1 of the present invention.

FIG. 6 is a flowchart of product virtual simulation (performance prediction and analysis) based on a constant operating condition according to Embodiment 1 of the present invention.

FIG. 7 is a flowchart of product virtual simulation (performance prediction and analysis) based on a constant design product according to Embodiment 1 of the present invention.

FIG. 8 is a schematic structural diagram of Embodiment 2 of the present invention.

FIG. 9 is a schematic diagram of a Junker test experiment according to Embodiment 1 of the present invention.

FIG. 10 is a variation curve diagram of preload with a number of cycles under different transverse vibration amplitudes in a physical experiment according to Embodiment 1 of the present invention.

FIG. 11 is a profile diagram of a thread cross section according to Embodiment 1 of the present invention.

FIG. 12 is a flowchart of constructing the hexahedral mesh finite element model of a bolted joint according to Embodiment 1 of the present invention.

FIG. 13 is a diagram for the bolted joint DT model according to Embodiment 1 of the present invention.

FIG. 14 is a variation curve diagram of preload with the number of cycles under different transverse vibration amplitudes according to Embodiment 1 of the present invention: (a) digital simulation (b) data fitting.

FIG. 15 is a digital simulation data organization diagram according to Embodiment 1 of the present invention: (a) for given IP and VA (b) for 33 combinations between IP and VA (c) all data testing data and training data.

FIG. 16 is a structural diagram of the bolted joint preload Rapid Virtual Simulation Model (RVSM) according to Embodiment 1 of the present invention.

FIG. 17 is a schematic diagram of evaluation metrics variation with epochs according to Embodiment 1 of the present invention: (a) MSE (b) MAE (c) MSLE.

FIG. 18 is a partial comparison diagram between the RVSM-based and digital simulation results under transverse vibration amplitudes ranging from 0.4 mm to 0.45 mm according to Embodiment 1 of the present invention: (a) 31.79 KN, 0.41 mm (b) 34.23 KN, 0.44 mm (c) 36.68 KN, 0.43 mm.

### DETAILED DESCRIPTION

It should be noted that, the following detailed descriptions are all exemplary, and are intended to provide further descriptions of the present disclosure. Unless otherwise specified, all technical and scientific terms used herein have the same meanings as those usually understood by a person of ordinary skill in the art to which the present disclosure belongs.

It should be noted that the terms used herein are merely used for describing specific implementations, and are not intended to limit exemplary implementations of the present disclosure.

The embodiments in the present invention and features in the embodiments may be mutually combined in case that no conflict occurs.

### Embodiment 1

This embodiment discloses a DT data model driven high-performance virtual simulation method.

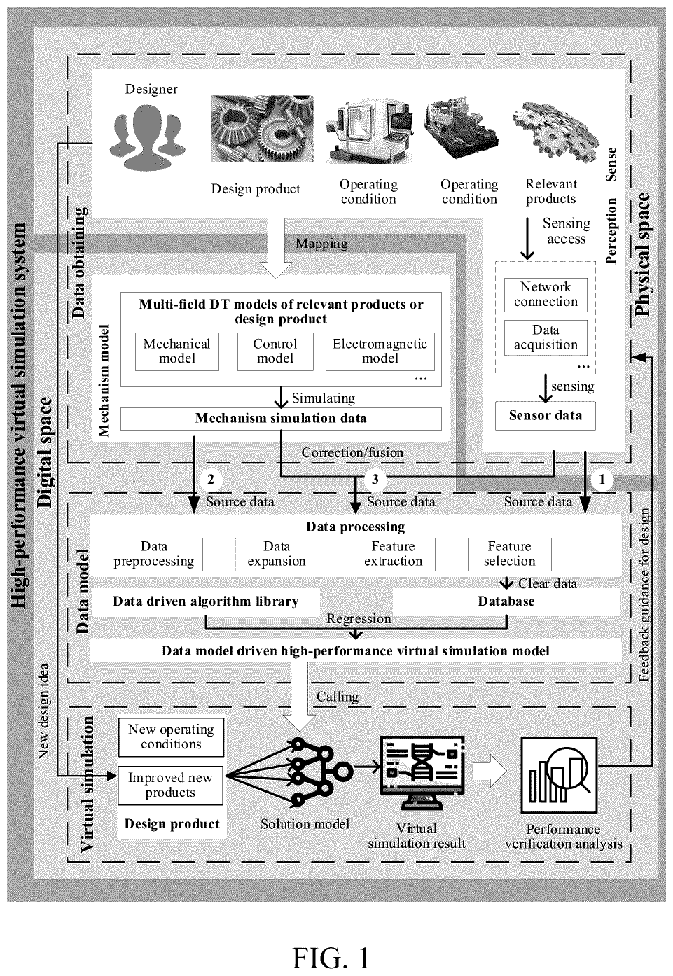

As shown in FIG. 1, the DT data model driven high-performance virtual simulation method includes:
based on a product design process, attention is paid to variable operating conditions or variable product structures to obtain three kinds of data relevant to the design product, relevant products, or operating conditions: sensor data, mechanism simulation data, and fusion data obtained by correcting the mechanism simulation data with the sensor data;
the obtained data is processed, the running mechanism is reversely resolved according to the data driven algorithm, and a data model driven high-performance virtual simulation model is built;
based on new operating conditions of the design product or improved new products, the built data model driven high-performance virtual simulation model is called to obtain virtual simulation results; and
performance of design product under new operating conditions or new products is analyzed according to the virtual simulation results to provide feedback guidance for product design.

In data obtaining, based on a product design process, attention is paid to variable operating conditions or variable product structures to obtain three kinds of data relevant to a design product, relevant products, or operating conditions: the sensor data, obtained through the product use process or physical experiment relevant to the product design; the mechanism simulation data, obtained by building multi-field DT models of relevant or design product and performing mechanism simulation on the relevant or design product and running conditions; and the fusion data, obtained by correcting the simulation data with the sensor data through a data correction algorithm.

In data driven modeling, one or more of the three kinds of data are processed, and the processed data is further concluded to a database. Then, relying on the data driven algorithm, through one or more of the three kinds of data, the running mechanism is reversely resolved according to an operating condition set or a product model set to build a data model driven high-performance virtual simulation model.

In virtual simulation, according to requirements of designers, based on new operating conditions of the design product or improved new products, the built data model driven high-performance virtual simulation model is called, product performance characterization virtual simulation results similar to digital simulation or a physical experiment are obtained, the performance of the design product under new operating conditions or new products is analyzed according to the simulation result, and feedback guidance is provided for product design.

The sensor data is obtained from the existing physical experiment relevant to the design product or the product running process, and has an effect of replacing simulation data or correcting simulation data. By considering the limitation of practical application scenarios, not all design products have the conditions for sensing physical data. Therefore, the sensor data is not available in all applications.

A reason for using a data fusion method is as follows: the quantity of the performance characterization sensor data obtained in practical process/physical experiment is small, but a great amount of performance characterization data is needed for building the data model driven high-performance virtual simulation model. Therefore, according to data correction algorithms, the performance characterization data obtained by mechanism simulation is corrected through the obtained performance characterization sensor data, so that the performance characterization data is more accurate, and the fusion data is obtained. The data correction algorithms include a particle swarm optimization (PSO) algorithm, a genetic algorithm, and an ant colony algorithm.

In a product high-performance virtual simulation process, the amount of product performance characterization data samples obtained through physical experiment/product practical running/DT mechanism model simulation respectively performed by focusing the above two situations needs to be great enough. Only in this way, the three kinds of obtained data can meet the requirement of respectively building the high-performance virtual simulation model in both cases.

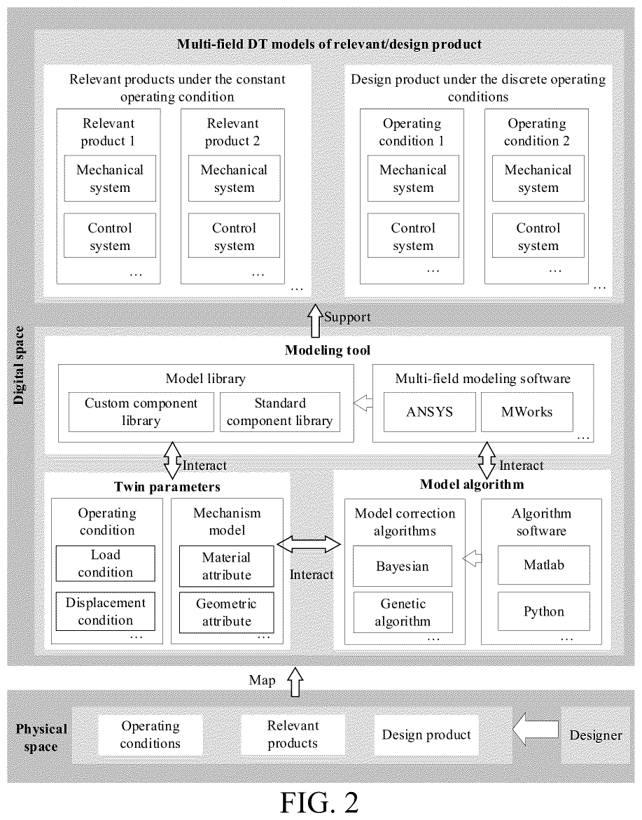

As shown in FIG. 2, a building process of the multi-field DT models of relevant products or design product is as follows:
based on a product design process, attention is paid to variable operating conditions or variable product structures, and twin parameters related to the product design in physical space are mapped, and are respectively the same operating condition of the relevant and design product and the structure attribute of relevant products, and the design product per se and variable operating conditions of the design product;
multi-field relevant products DT models under a constant operating condition or multi-field design product DT models under discrete operating conditions including different systems such as a mechanical system, a control system and an electromagnetic system are built based on modeling tools, model correction algorithms, and the mapped twin parameters.

The model correction mainly refers to the correction on the model twin parameters, and includes global optimization, local optimization, and combined optimization on the model by using model correction algorithms such as Bayesian and the genetic algorithm.

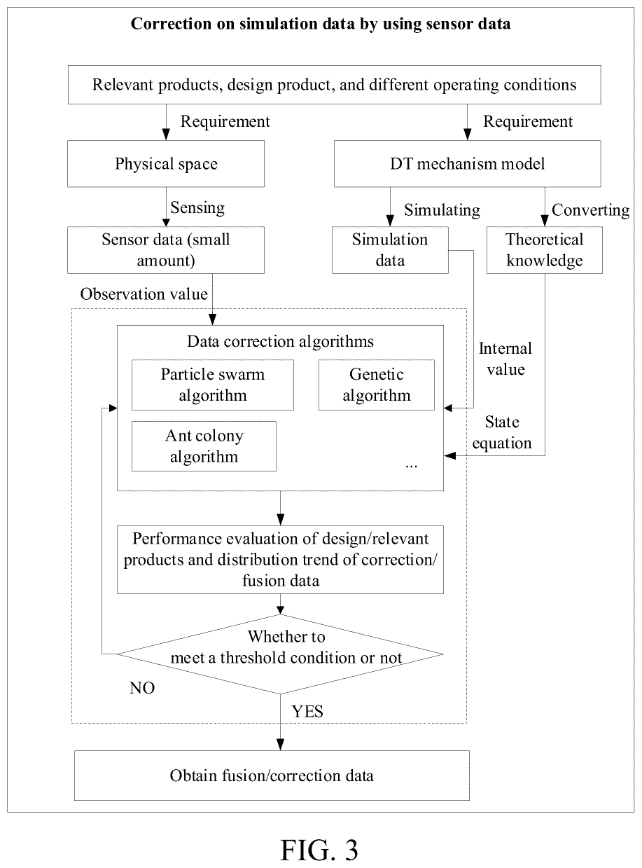

As shown in FIG. 3, a specific process of correcting the simulation data by the product performance characterization sensor data is as follows:
according to the variable operating conditions or variable product structures relevant to product design, a small amount of sensor data in the product use process/physical experiment and the mechanism simulation result of multi-field DT models of design or relevant products are obtained, and the DT model building theory is converted into a state space model;
a proper model correction algorithm is selected, and a correction threshold is set according to application requirements. Moreover, the sensor data is set to be an observation equation of the data model correction process, the state model is fused into a state equation of the correction algorithm, and the obtained mechanism simulation result is used as an internal value of the correction algorithm;
the obtained mechanism simulation data is input into the model correction algorithm to output result data, the performance of the design product or relevant products is evaluated, the distribution trends of the sensor data, the simulation data, and the result data are compared, and whether the result data meets the set threshold condition or not is analyzed. If the result data meets the set threshold, the fusion/correction data is outputted, and if the result data does not meet the set threshold, the model correction algorithm is selected again for iteration.

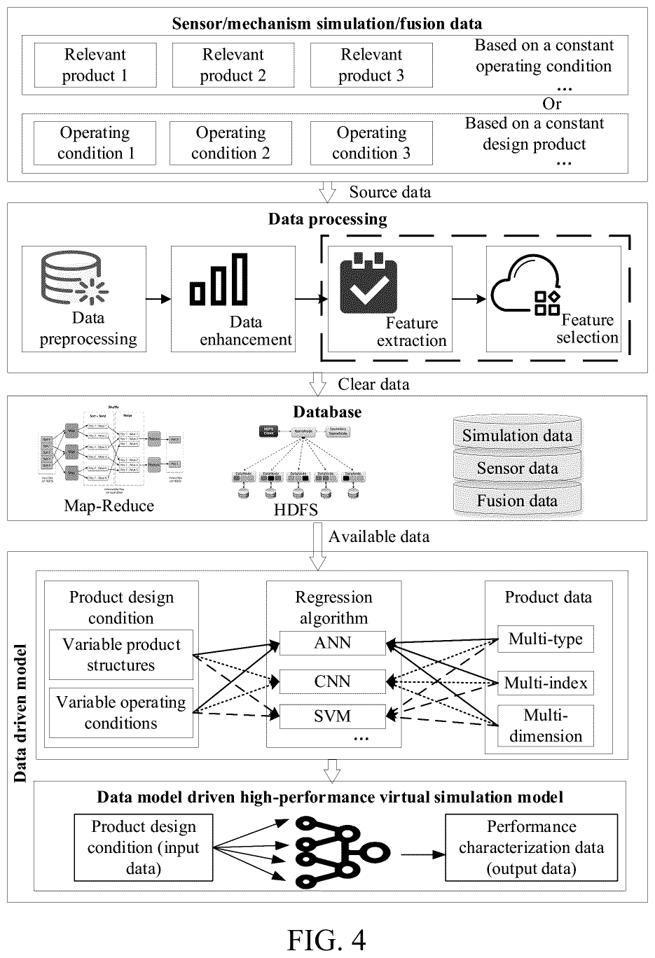

As shown in FIG. 4, a specific building process of a DT data model driven high-performance virtual simulation system is as follows:
the sensor data of the physical experiment/product use process based on the constant operating condition or design product, the mechanism simulation result data of the built multi-field DT models of relevant products or design product, and the fusion data obtained through the data correction algorithm are obtained;
one or more of the three kinds of data are processed, and the processed data is further concluded to a database for subsequent data mining;
from an aspect of big data, the processed data is stored into a database for order management and relevant data organization;
the product design condition of the variable operating conditions or variable product structures is set, a regression algorithm is selected and trained according to multi-type multi-index and multi-dimension product data, and the data model driven high-performance virtual simulation model is built.

The data processing may include data preprocessing, data expansion, feature extraction, and feature selection, the feature extraction and the feature selection are selectively determined according to the data driven algorithm, which is unnecessary, and the data expansion is expansion on the magnitude of the simulation data through the algorithm.

The data model driven high-performance virtual simulation model is a data regression black box model built using regression algorithms with the product design condition as input and the performance characterization data as output. The regression algorithm includes CNN, ANN, SVM, etc.

The data model driven high-performance virtual simulation model built according to the application requirement for the constant operating condition or design product is multifunctional. For example, the virtual simulation analysis on the variable product structures stress and strain under the same operating condition only needs to build a data model driven high-performance virtual simulation model for stress and strain, so that the improved product performance analysis is supported.

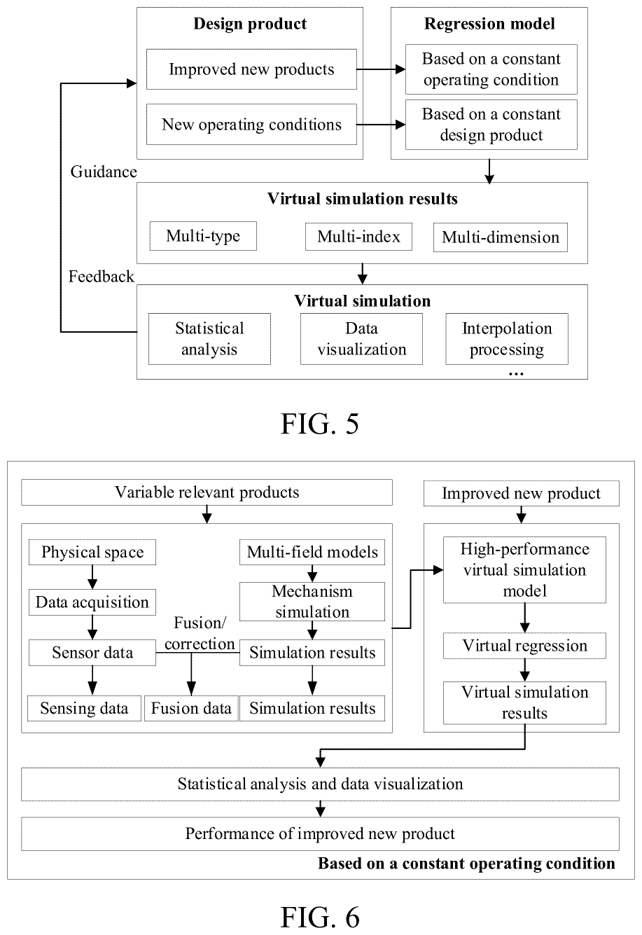

As shown in FIG. 5, an implementation process of design product virtual simulation (performance prediction and analysis) is as follows:
based on the design product's new operating conditions or new improved products, a regression model driven by the data model for the constant operating condition or constant design product is respectively called, and the virtual simulation results similar to the digital simulation/physical experiment/running experiment are outputted;
the performance of the design product is further analyzed and predicted by data methods such as statistical analysis, data visualization, and interpolation processing to guide the product design.

Specifically, based on the virtual simulation (product performance verification) under the constant operating condition, as shown in FIG. 6, firstly, the sensor data of relevant products under the constant operating condition is obtained based on the existing physical experiment/running experiment, the mechanism simulation of relevant products is performed to obtain the mechanism simulation data, and moreover, the fusion data is obtained based on the data correction algorithm. Then, the high-performance virtual simulation model is built based on one or more of the above three product performance characterization data. Finally, virtual simulation data of the improved new product is predicted, and the performance of the improved new product is analyzed through statistical analysis, data visualization, etc.

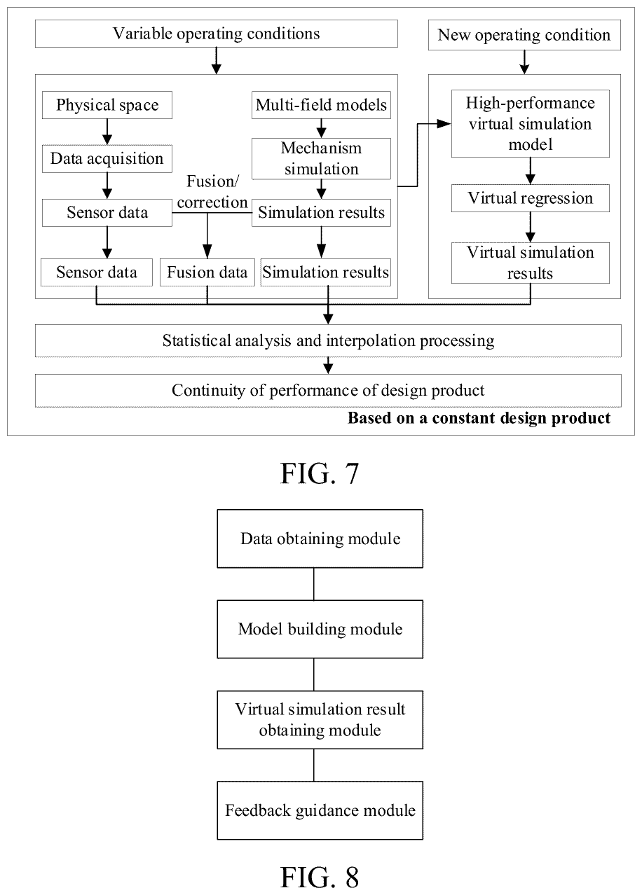

Specifically, based on the virtual simulation (product performance verification) of the constant design product, as shown in FIG. 7, firstly, the sensor data of the design product under the variable operating conditions is obtained based on the existing physical experiment/running experiment, the mechanism simulation on variable operating conditions is performed to obtain the mechanism simulation data, and moreover, the fusion data is obtained based on the data correction algorithm. Then, the high-performance virtual simulation model is built based on one or more data in the three above product performance characterization data. Finally, the virtual simulation data under new operating conditions is deduced, the data is fused into the product performance characterization data through statistical analysis, interpolation processing, etc., and the performance of the design product under continuous operating conditions is analyzed.

As mentioned above, the high performance virtual simulation method driven by the digital twin data model provided in this embodiment is applicable to the iterative optimization design of the product and the analysis of the performance of the design product under continuous operating conditions, that is, the embodiment is aimed at the two conditions of variable operating conditions or variable product structures. Next, a DT data-driven product performance rapid virtual simulation method for variable operating conditions is proposed in this embodiment.

According to evaluating a critical loosening load of a bolted joint, the effectiveness and operability of the DT data-driven product performance rapid virtual simulation method for variable operating conditions are verified.

The bolted joint operating conditions description are as follows:

The form of external load on the bolt is complex and generally equivalent to cyclic load: force and displacement. The external cyclic load displacement can be expressed as follows:

\vec{A}=A₀ sin(ωt)\vec{i} (1)

Where A₀ is a maximum value of displacement amplitude, ω is an angular velocity and the relationship between the angular velocity and frequency fis expressed as follows.

ω2πƒ (2)

It is found that both vibration amplitude and frequency are factors that affect bolted joint loosening failure, but amplitude is the main factor. Therefore, in this embodiment, the 8.8 M12*55 bolt is selected as the research object, and the transverse load displacement amplitude is set according to the vibration conditions. The key parameters of the bolt are: the thread diameter is 12 mm, the pitch is 1.75 mm, the total length is 55 mm, the thread length is 30 mm, and the bolt head diameter is 20mm.

### Product Performance Rapid Virtual Simulation Approach Driven by DT Data for Critical Loosening Load Evaluation of Bolted Joint

To make the DT data-driven product performance rapid virtual simulation method for variable operating conditions better serve critical loosening load evaluation of the bolted joint, the following will introduce in detail from twin data acquisition of bolted joint under different operating conditions, twin data-driven preload Rapid Virtual Simulation Model (RVSM) construction for critical loosening load evaluation of bolted joint, and critical loosening load-rapid evaluation of bolted joint based on RVSM.

### Twin Data Acquisition for Bolted Joint under Different Operating Conditions

Digital simulation data of the bolted joint under different operating conditions are selected as the data source for application verification, and a small amount of sensor data is obtained to provide characteristic information for the construction of bolted joint DT models.

### (1) Sensor Data Acquisition for Bolted Joint under Different Operating Conditions

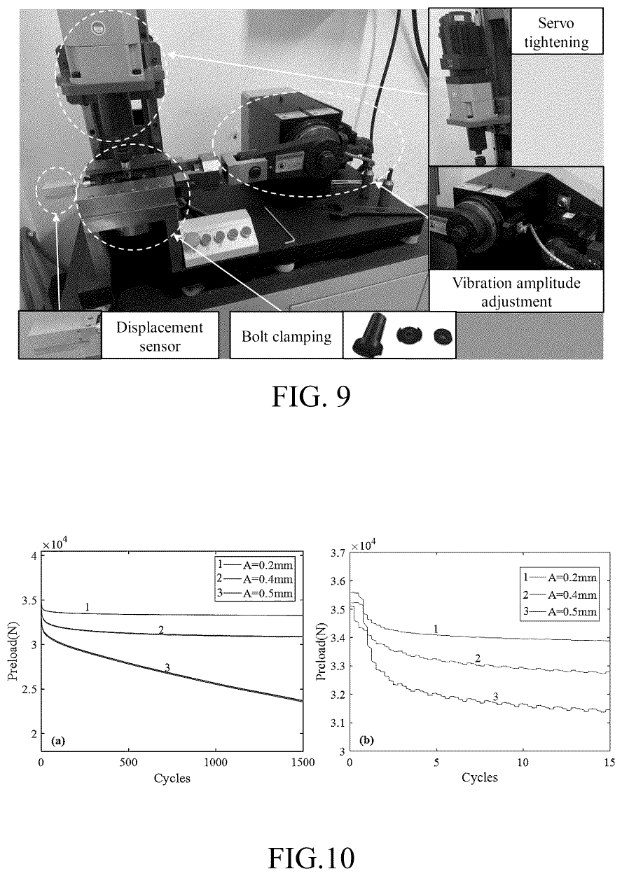

In the embodiment, a limited amount of sensor data is obtained through the physical experiment. As shown in FIG. 9, a fastener transverse vibration test device (Junker test equipment) is utilized. During the test process, a sample clamping device fixes the bolt and nut, and a servo-tightening device applies a set initial preload to the bolt and nut. Then, a transverse displacement is set, and a transverse vibration applied to the bolted joint is generated by an amplitude adjustment device. Meanwhile, three sensors are used to monitor transverse force, preload, and transverse displacement. As a loss of preload directly reflects a degree of bolt loosening, a variation of preload with a number of cycles is selected as performance characterization data in this embodiment. Three test conditions are set. At the same time, to ensure the effectiveness of the data, each condition is tested three times. Experiment results are shown in FIG. 10.

The conditions such as amplitude (A), cycles, frequency, and initial preload set in the physical experiment are twin information to construct DT models of the bolted joint under different operating conditions. However, in this embodiment, in addition to setting the transverse vibration amplitude as a condition variable, the influence of initial preload on the critical loosening load of the bolted joint is also considered, and initial preload is also a condition variable. In this embodiment, only partial vibration amplitude under one initial preload is set, and the variation results of preload under different initial preloads are not obtained. The detailed operating conditions for the loosening analysis of the bolted joint are described in the acquisition of digital simulation data.

From FIG. 10, it can be seen that an increase in vibration amplitude has a significant influence on the variation of preload during bolt loosening. The experiment results are in line with theoretical expectations, and the obtained sensor data are feasible. The sensor data is further used for constructing the high-fidelity DT model of bolted joint.

### (2) Digital Simulation Data Acquisition for Bolted Joint under Different Operating Conditions

To respond to physical experimental scenarios and obtain digital simulation data on the variation of preload with the number of cycles under different transverse vibration amplitudes, this embodiment uses an Abaqus and a HyperMesh modeling software to construct the bolted joint DT models. With reference to the Junker experiment, the DT model of the bolted joint comprises four parts: an upper connected part, a lower connected part, a bolt, and a nut.

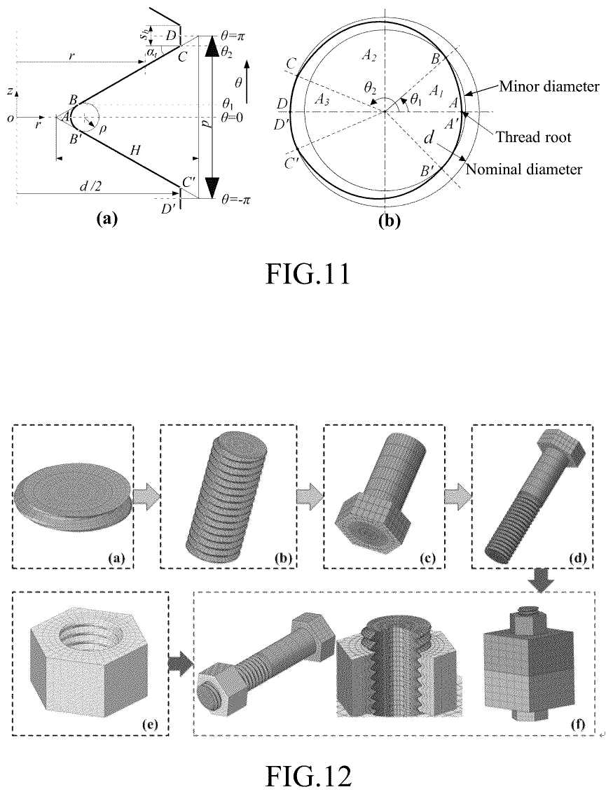

During the process of constructing DT models, considering the influence of thread rising angle on the loosening of the bolted joint, a hexahedral finite element modeling method proposed by Fukuoka is utilized to construct the fine model of the bolted joint. In this method, a thread cross section along a bolt axis is shown in FIG. 11(a), and the cross section profile of an external thread perpendicular to the bolt axis is shown in FIG. 11(b). A equation expression of the external thread profile is as follows.

$$r = \{ \begin{matrix}\frac{d}{2} - \frac{7}{8} H + 2 ρ - \sqrt{{ρ}^{2} - \frac{{P}^{2}}{4 {π}^{2}} {θ}^{2}} \\ \frac{H}{π} θ + \frac{d}{2} - \frac{7}{8} \\ \frac{d}{2}\end{matrix} \begin{matrix}\begin{matrix}( 0 \leq θ \leq {θ}_{1} ) \\ ( {θ}_{1} \leq θ \leq {θ}_{2} )\end{matrix} \\ ( {θ}_{2} \leq θ \leq π )\end{matrix} \qquad ( 3 )$$

$${θ}_{1} = \frac{\sqrt{3} π}{P} ρ , {θ}_{2} = \frac{7}{8} π , ρ \leq \frac{\sqrt{3}}{12} P , H = \frac{\sqrt{3}}{2} P$$

Where P is an external thread pitch, ρ is a root radius of the external thread, and d and H are a nominal diameter and thread overlap. In addition, an internal thread profile has the same characteristics and can be expressed by a similar mathematical equation, which is no further elaboration here.

Based on the above methods, in this embodiment, a process of fine finite element model of the bolted joint is constructed by HyperMesh software, as presented in FIG. 12, and a specific procedure is as follows.
(a) Firstly, a one-pitch hollow mesh model of the external thread is constructed using HyperMesh and MATLAB software. MATLAB is mainly used to calculate a node information of the external thread using the above equation. Then, a structured hexahedral mesh is generated by the stretching method to fill a hollow area of a bolt core, and the one-pitch thread fine finite element model is constructed, as shown in FIG. 12(a).
(b) The one-pitch fine finite element model of the external thread is translated and copied to construct the threaded part fine finite element model, as shown in FIG. 12(b). Assuming that a length of the threaded part is H and one pitch is h, then copy times are H/h.
(c) A actual geometric dimensions of a screw (without thread) and a bolt head are established. Then, based on a bolt core mesh model, the mesh is smoothed onto the screw and head in a common node manner, and the fine finite element model of a remaining part of the bolt is constructed, as shown in FIG. 12(c).
(d) A threaded part model and the remaining bolt part model are assembled and fused, and the bolt fine finite element model is constructed, as shown in FIG. 12(d).
(e) A nut fine finite element model is created in the same way, as shown in FIG. 12(e).
(f) The geometric dimensions of the upper and lower connected parts are established, which are 35 mm×35 mm×20.5 mm, and mesh divisions of the connected parts are carried out. Then, the constructed bolt model, nut model, and upper and lower connected part model are assembled and fused, and the hexahedral mesh finite element model of the bolted joint is constructed, as shown in FIG. 12(f).

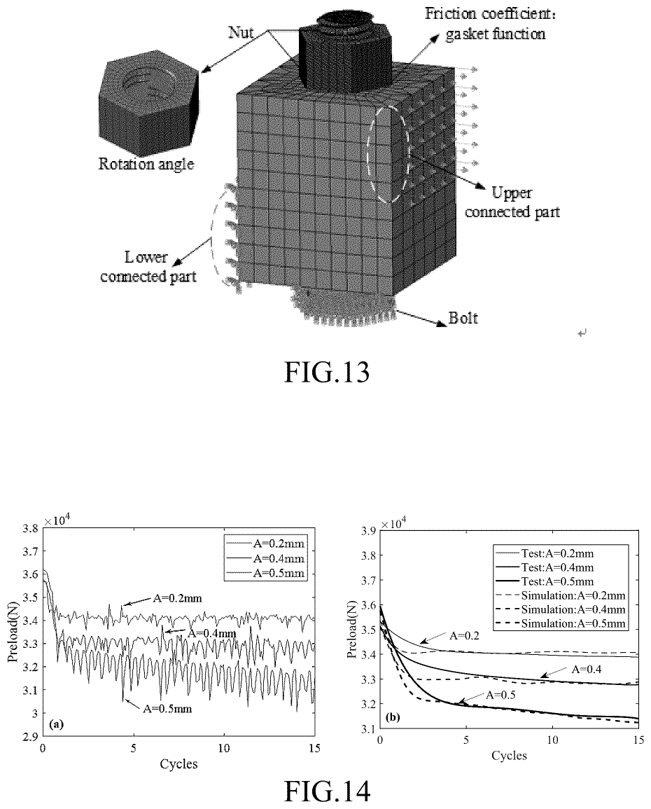

Then, the fine finite element model of the bolted joint built above is imported into Abaqus software. Subsequently, twin information is set, such as material properties and operating conditions, to simulate actual physical experiment scenarios. The bolt and nut are considered elastic-plastic models, and connected parts are considered elastic models. The friction coefficient between the internal and external thread is set to 0.15, while that of the other parts is 0.1. At the same time, the preload is applied to the bolted joint with the rotation angle method, which is variable. The lower connected part remains fixed, and the upper connected part is subjected to the transverse load in the form of displacement. The displacement function is equation (1), where the vibration amplitude is variable, and ƒ is 12.5 Hz. Finally, the DT model of the bolted joint is constructed and presented in FIG. 13.

For the verification of the DT model of the bolted joint, variation results of preload obtained by experiment test and digital simulation are compared. First, with reference to the experiment conditions set above, the constructed DT model of the bolted joint is solved in the Abaqus software, the number of transverse loading cycles is 15, and digital simulation data under three conditions are acquired. The digital simulation results are shown in FIG. 14(a). Then, curve fitting is carried out on the simulation results in MATLAB software, followed by a similar operation implemented in the first 15 cycles of experiment results. Data fitting results are shown in FIG. 14 (b).

It shows that there is good consistency between the experiment result and the digital simulation result. To quantitatively analyze the error between the two results, a deviation percentage of a preload decrease value is used as an evaluation index, expressed as follows.

$${D}_{e v} = \frac{Δ {P}_{s} - Δ {P}_{e}}{Δ {P}_{e}} \qquad ( 4 )$$

Where ΔPₛ represents the preload decrease in digital simulation, ΔPₑ represents the preload decrease in the experiment. Dₑᵥ is the deviation between the simulated preload decrease value and the experimental preload decrease value. In this embodiment, the initial preload is P₀, the preload after 15 cycles is P₁₅, and the preload decrease is ΔP=P₀−P₁₅.

At the same time, the deviation between them calculated by equation (4) is about 11%, which is acceptable. Therefore, the accuracy of the DT model is verified. The set parameters will serve as necessary twin information for constructing DT models of the bolted joint under different operating conditions (different initial preload and different transverse vibration amplitudes) here.

To obtain sufficient digital simulation data, the vibration amplitude and initial preload are listed in detail here. The variation amplitude of the bolted joint ranges from 0.1 mm to 0.6 mm, where the increment value between each digital simulation is 0.05 mm. There are three different initial preloads, which are 31.79 KN, 34.23 KN, and 36.68 KN. Finally, 33 bolted joint DT models are constructed and simulated in Abaqus, including three models constructed above FIG. 14. Then, 33 sets of digital simulation data are acquired, which will be utilized to construct the twin data-driven bolted joint preload RVSM.

### Twin Data-Driven Preload RVSM Realization for Critical Loosening Load Evaluation of Bolted Joint

An Artificial Neural Network (ANN) is selected as a data-driven algorithm to construct the bolted joint preload RVSM. The twin data-driven preload RVSM for critical loosening load evaluation of the bolted joint is realized in this section. The whole process is carried out in Jupyter Notebook, in which the Python language is used. The following will briefly describe the realization process.

### (a) Determination of an Output Variable and an Input Variable

As mentioned above, the initial preload and transverse vibration amplitude are variable, and the variation of preload with the number of cycles is the performance characterization data. Therefore, the variation of preload is dominated by these two condition variables. At the same time, the variation of preload is closely related to the number of cycles. Therefore, the input variables of the ANN model are initial preload (IP), transverse vibration amplitude (VA), and transverse vibration loading cycles (LC), while the output variable is preload variation (PV).

### (b) Digital Simulation Data Organization and Processing

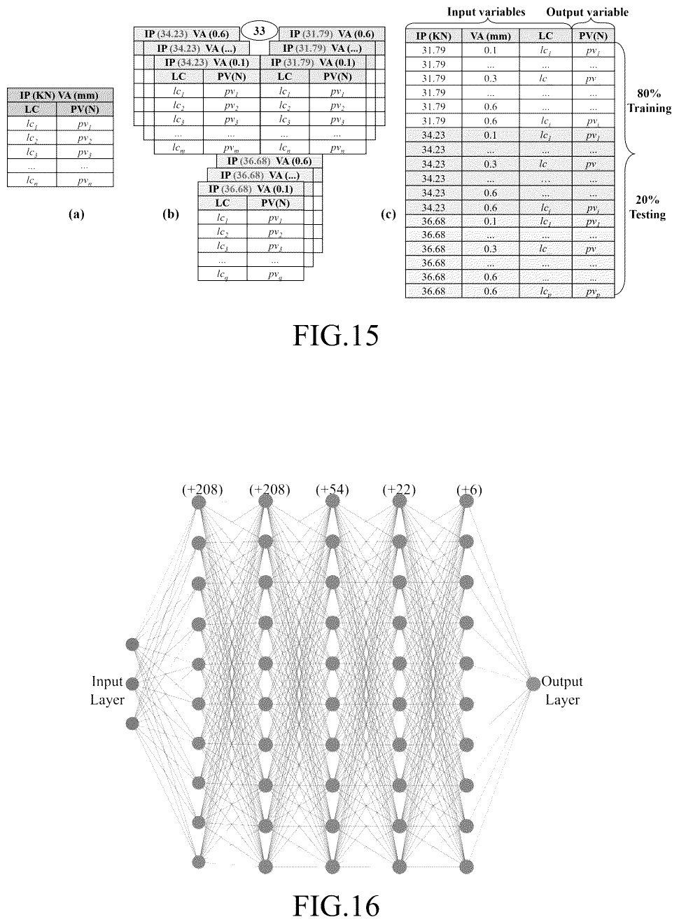

For digital simulation data organization, each operating condition for a given initial preload and vibration amplitude corresponds to a CSV file, which presents the above four-dimensional variables, as depicted in FIG. 15(a). Since 3 types of initial preload and 11 types of vibration amplitude are set, 33 digital simulations are conducted in Abaqus software to obtain 33 sets of digital simulation data related to the initial preload and vibration amplitude, as shown in FIG. 15(b). The data points of each operating condition are 200. Finally, all data related to different operating conditions from different CSV files are organized into one file, as illustrated in FIG. 15(c), with the support of the Pandas library. Since the dataset gathered in this embodiment is not considered big data, data organization is not performed by a database.

For digital simulation data processing, to improve the effectiveness of ANN model training, the data organized is normalized by a MinMaxScaler function, which can map all data to the range of [0, 1]. At the same time, it is necessary to divide the data into training data and testing data. Thus, data splitting is achieved by a train_test_split function, which can randomly divide all data. For the embodiment, a ratio of training data to testing data is 8:2, and random_state is 2022. Digital simulation data normalization and splitting are both done by calling a Sklearn library.

### (c) Bolted Joint Preload RVSM Structure Construction

The preload RVSM structure for (ANN regression model) is constructed by a Sequential model, which is composed of five fully connected layers (dense/hidden layer) and a output layer (dense layer). For this model, except for the output layer, a ReLU is used as an activation function in each layer. As the input layer, a first layer contains 218 neurons and accepts three input variables. Next four fully connected layers have 218, 64, 32, and 16 neurons, respectively. In a last layer (output layer), there is only one neuron, which is used to output the regression results (an output variable), and the activation function is linear. The preload RVSM structure construction is done by calling a TensorFlow 2.5.0 library. The structure of bolted joint preload RVSM based on the ANN network is shown in FIG. 16.

Further, the model is compiled. A loss function is a mean square error (MSE), and an adaptive moment estimation (Adam) is selected as the optimizer to update parameters. In addition, a mean absolute error (MAE), a mean square logarithmic error (MSLE), and the MSE are designated as evaluation metrics.

### (d) Bolted Joint Preload RVSM Training and Testing Based on Digital Simulation Data

After building the bolted joint preload RVSM structure, a fit method is used to train the model.

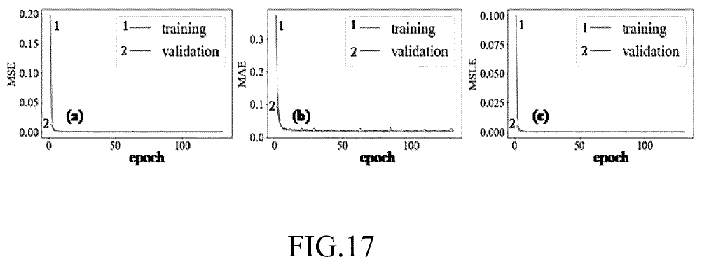

The variation of evaluation metrics with epochs is listed in FIG. 17. It can be seen that after 131 epochs, these metrics stabilize, indicating that training the model requires 131 epochs. In addition, the training time takes 27.3 s. Meanwhile, during both model training and validation, three evaluation metrics decrease with increasing the number of epochs. Moreover, as one of evaluation indicators, MSE also serves as the loss function, thus showing a similar trend. Overall, the validation results demonstrate that the model has a good generalization performance.

After the training, the model performance is evaluated by using test data. The loss function and evaluation metrics of the model are calculated. The obtained results are LOSS=9.4557e-04, MAE-0.0205, MSE=9.4557e-04, and MSLE=3.7634e-04. The evaluation metrics perform well, demonstrating the feasibility of the constructed bolted joint preload RVSM. Later, it will be used to rapidly predict the variation of preload under new operating conditions, thereby promoting the rapid estimation of the critical loosening load of the bolted joint.

### Critical Loosening Load Rapid-Evaluation of Bolted Joint Based on RVSM

As can be seen from the above, the bolted joint preload RVSM can be used to rapidly predict the variation result of preload with the number of cycles under new operating conditions. In this embodiment, the critical loosening load of the bolted joint can be determined rapidly based on the constructed RVSM.

Firstly, to preliminarily measure a loosening degree of the bolt, a decreasing rate of preload for 33 sets of digital simulation results obtained above is calculated. The results are shown in Table 1. The decreasing rate of preload is expressed as follows.

$$D \% = ( 1 - \frac{{P}_{15}}{{P}_{0}} ) \times 100 \qquad ( 5 )$$

where P₀ is also the initial preload value and P₁₅ is also the preload value after 15 cycles.

It can be seen from the Table 1 that the preload of the bolted joint shows a decreasing trend under different vibration amplitudes. At the same time, for the three different initial preloads, when the vibration amplitude is less than or equal to 0.4 mm, after 15 vibration cycles, the decreasing rate of preload is all not more than 10%, and the variation of decreasing rate between adjacent amplitudes is all around 2%. However, when the amplitude is transitioned from 0.4 mm to 0.45 mm, the decreasing rate of preload reaches over 10%, and the variation of the decreasing rate significantly increases. Therefore, for the three different initial preloads, the transverse vibration amplitude corresponding to the critical loosening load of the bolted joint should be between 0.4 mm and 0.45 mm.

TABLE 1
Decreasing results of preload under different transverse
vibration amplitudes and initial preloads

| | |
|---|---|
| VA | Decreasing rate of preload (%) |

| Case | (mm) | 31.79 KN | 34.23 KN | 36.68 KN |
|---|---|---|---|---|
| 1 | 0.1 | 0.5% | 0.6% | 1.0% |
| 2 | 0.15 | 2.5% | 2.4% | 1.7% |
| 3 | 0.2 | 4.1% | 3.8% | 4.0% |
| 4 | 0.25 | 5.2% | 5.3% | 4.8% |
| 5 | 0.3 | 6.6% | 7.2% | 6.3% |
| 6 | 0.35 | 8.3% | 8.1% | 7.2% |
| 7 | 0.4 | 9.1% | 9.1% | 7.9% |
| 8 | 0.45 | 13.6% | 12.6% | 11.4% |
| 9 | 0.5 | 15.0% | 14.5% | 13.1% |
| 10 | 0.55 | 22.1% | 21.6% | 19.5% |
| 11 | 0.6 | 25.6% | 24.7% | 21.4% |

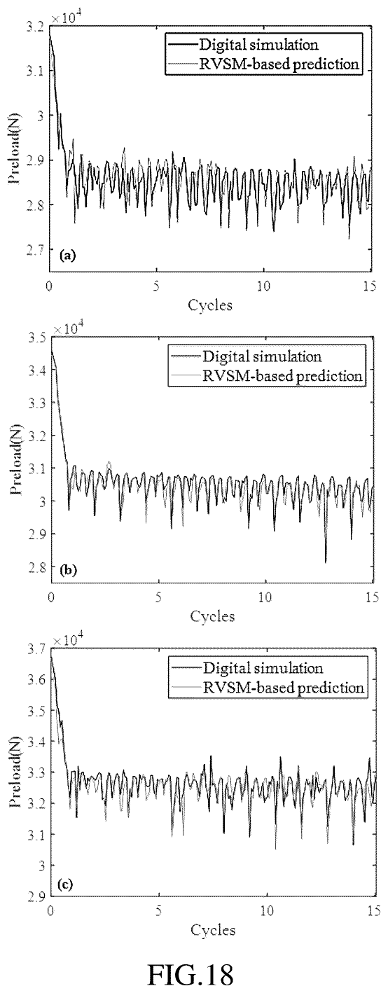

Further, to quickly determine the transverse vibration amplitude corresponding to the critical loosening load of the bolted joint, the simulation experiment of bolt loosening with the vibration amplitudes ranging from 0.4 mm to 0.45 mm is performed based on the constructed RVSM. Firstly, for three different initial preload conditions, the amplitude is subdivided into 0.41 mm, 0.42 mm, 0.43 mm, and 0.44 mm, resulting in the generation of 12 new operating conditions. Then, to obtain the variation of preload with the number of cycles, it is necessary to specify the number of cycles. Thus, the same number of vibration cycles as the digital simulation, which is 15 cycles, is chosen. Consequently, for each of the 12 operating conditions, there are 200 data points. Finally, the bolted joint preload RVSM is utilized, by inputting 12 new operating conditions variables into the RVSM, including three initial preload values, 12 transverse vibration amplitudes, and 15 cycles (200 data points), and the variation results of preload with the number of cycles for three initial preload conditions are predicted by RVSM. The RVSM-based predictions and digital simulation results for three initial preload conditions are shown in FIG. 18, with FIG. 18(a) 31.79 KN, 0.41 mm, FIG. 18(b) 34.23 KN, 0.44 mm, and FIG. 18(c) 36.68 KN, 0.43 mm.

Similar to previous findings, under different transverse amplitude conditions ranging from 0.4 mm to 0.45 mm, the preload of the bolted joint shows a decreasing trend. To ultimately determine the transverse vibration amplitude corresponding to the critical loosening load from the loosening degree of the bolt, the decreasing rate of preload is further calculated, and the results are shown in Table 2.

TABLE 2
Decreasing results of preload under transverse vibration amplitudes
ranging from 0.4 mm to 0.45 mm and three initial preloads

| | |
|---|---|
| VA | Decreasing rate of preload (%) |

| Case | (mm) | 31.79 KN | 34.23 KN | 36.8 KN |
|---|---|---|---|---|
| 1 | 0.41 | 9.3% | 9.4% | 8.4% |
| 2 | 0.42 | 9.5% | 9.7% | 8.6% |
| 3 | 0.43 | 11.6% | 11.1% | 10.3% |
| 4 | 0.44 | 12.1% | 11.8% | 10.8% |

It can be seen that, for the three different initial preloads, when the vibration amplitude exceeds 0.42 mm, the decreasing rate of preload exceeds 10%. Additionally, when the amplitude increases from 0.42 mm to 0.43 mm, the variation of decreasing rate exceeds 1%. In contrast, the variation of decreasing rate between adjacent amplitudes in other ranges is within 1%. Therefore, the vibration amplitude corresponding to the critical loosening load should be between 0.42 mm and 0.43 mm. From the practical safety perspective, it is advisable to select a smaller vibration amplitude. Therefore, for the three different initial preloads, the transverse load corresponding to an amplitude of 0.42 mm is the critical loosening load of the bolted joint in this embodiment.

### Application Result Analysis for Product Performance Rapid Virtual Simulation Approach Driven by DT Data for Variable Operating Conditions

From FIG. 18, it can be seen that RVSM-based predictions have a similar trend to digital simulation (Abaqus simulation) results. To more intuitively evaluate the rapidity and accuracy of the DT data-driven product performance rapid virtual simulation method in determining the critical loosening load of the bolted joint, for the 12 variable operating conditions, the RVSM-based results are compared with the digital simulation results. A mean relative error (MRE) is selected as the evaluation indicator. In addition, the computational cost of two methods for solving the 12 cases is calculated. The results are shown in Table 3.

TABLE 3
Comparison results between RSM-based and digital
simulation for the 12 new operating conditions

| | IP | VA | Data | RSM | Abaqus | MRE |
|---|---|---|---|---|---|---|
| Case | (KN) | (mm) | points | prediction(s) | simulation(h) | (%) |
| 1 | 31.79 | 0.41 | 200 | ≈1.0 s | ≈10.42 h | 0.79 |
| 2 | | 0.42 | | | | 0.91 |
| 3 | | 0.43 | | | | 0.93 |
| 4 | | 0.44 | | | | 0.76 |
| 5 | 34.23 | 0.41 | | | | 0.29 |
| 6 | | 0.42 | | | | 0.68 |
| 7 | | 0.43 | | | | 0.86 |
| 8 | | 0.44 | | | | 0.62 |
| 9 | 36.68 | 0.41 | | | | 0.86 |
| 10 | | 0.42 | | | | 0.75 |
| 11 | | 0.43 | | | | 0.82 |
| 12 | | 0.44 | | | | 0.88 |

As can be seen in Table 3, in terms of accuracy, for 12 new operating conditions, the MRE between RVSM-based results and digital simulation results is within 1%, which indicates that the bolted joint preload RVSM constructed has an accuracy of up to 99% for predicting the variation of preload with the number of cycles under variable operating conditions. In terms of rapidity, RVSM is approximately 37512 times faster than Abaqus. Compared with the Abaqus calculation, after the model training, the RVSM can rapidly respond to new operating conditions, predict the variation of preload with the number of cycles, and further facilitate accurate and rapid determination of the transverse vibration amplitude corresponding to the critical loosening load. Therefore, the proposed product performance rapid virtual simulation method driven by DT data for variable operating conditions is feasible for rapidly and accurately evaluating the critical loosening load of the bolted joint.

### Embodiment 2

This embodiment discloses a DT data model driven high-performance virtual simulation system.

As shown in FIG. 8, the DT data model driven high-performance virtual simulation system includes:
a data obtaining module, configured to: based on a product design process, pay attention to variable operating conditions or variable product structures to obtain three kinds of data relevant to a design product, relevant products, or operating conditions: sensor data, mechanism simulation data, and fusion data obtained by correcting the mechanism simulation data with the sensor data;
a model building module, configured to: process the obtained data, reversely resolve running mechanism according to the data driven algorithm, and build a data model driven high-performance virtual simulation model;
a virtual simulation result obtaining module, configured to: based on new operating conditions of the design product or improved new products, call the built data model driven high-performance virtual simulation model to obtain virtual simulation results; and
a feedback guidance module, configured to: analyze performance of design products under new operating conditions or new products according to the virtual simulation results to provide feedback guidance for product design.

### Embodiment 3

This embodiment is directed to provide a computer-readable storage medium.

The computer-readable storage medium stores a computer program. The program implements the steps of the DT data model driven high-performance virtual simulation method according to Embodiment 1 of the present invention when being executed by a processor.

### Embodiment 4

This embodiment is directed to provide an electronic device.

The electronic device includes a memory, a processor, and a program stored on the memory and capable of running on the processor. The processor implements the steps of the DT data model driven high-performance virtual simulation method according to Embodiment 1 of the present invention when executing the program.

Each step and method involved in the device according to Embodiment 2, Embodiment 3, and Embodiment 4 correspond to Embodiment 1, and references may be taken to relevant descriptions in Embodiment 1 for the specific implementations. The term “computer-readable storage medium” should be understood as a single medium or multiple media including one or more instruction sets, and should be also be understood to include any medium capable of storing, encoding or carrying instruction sets executed by a processor and enabling the processor to perform any one method of the present invention.

It should be understood by those skilled in the art that each module or each step of the present invention can be implemented by a general-purpose computer device. Optionally, they may be implemented by using program codes executable by a computing device, so that they may be stored in a storage device to be executed by the computing device, or they may be respectively made into individual integrated circuit modules, or multiple modules or steps in them may be made into a single integrated circuit module for implementation. The present invention is not limited to any specific combination of hardware and software.

The specific implementations of the present invention are described above with reference to the accompanying drawings, but are not intended to limit the protection scope of the present invention. A person skilled in the art should understand that various modifications or deformations may be made without creative efforts based on the technical solutions of the present invention, and such modifications or deformations shall fall within the protection scope of the present invention.

1. A digital twin (DT) data model driven high-performance virtual simulation method, comprising:
based on a product design process, paying attention to variable operating conditions or variable product structures to obtain three kinds of data relevant to a design product, relevant products, or operating conditions: sensor data, mechanism simulation data, and fusion data obtained by correcting the mechanism simulation data with the sensor data; processing the obtained data, reversely resolving the running mechanism according to the data driven algorithm, and building a data model driven high-performance virtual simulation model;
based on new operating conditions of the design product or improved new products, calling the built data model driven high-performance virtual simulation model to obtain virtual simulation results; and
analyzing performance of the design product under new operating conditions or new products according to the virtual simulation results to provide feedback guidance for product design.

2. The DT data model driven high-performance virtual simulation method according to claim 1, wherein the sensor data is obtained through the product use process or the physical experiment relevant to the product design; the mechanism simulation data is obtained by building multi-field DT models of relevant products or the design product and performing mechanism simulation on the relevant products or the design product and running conditions; and the fusion data is obtained by correcting the simulation data with the sensor data.

3. The DT data model driven high-performance virtual simulation method according to claim 2, wherein the building multi-field DT models of relevant products or the design product specifically comprises:
based on a product design process, paying attention to variable operating conditions or variable product structures and mapping twin parameters related to the product design in physical space; and building multi-field relevant product DT models under the constant operating condition or multi-field design product DT models under discrete operating conditions based on modeling tools, model correction algorithms, and the mapped twin parameters.

4. The DT data model driven high-performance virtual simulation method according to claim 2, wherein the operation that the fusion data is obtained by correcting the simulation data with the sensor data specifically comprises:
based on data correction algorithms, correcting the performance characterization simulation data obtained by mechanism simulation through a small amount of obtained performance characterization sensor data, the data correction algorithms comprising the particle swarm optimization (PSO) algorithm, the genetic algorithm, and the ant colony algorithm.

5. The DT data model driven high-performance virtual simulation method according to claim 1, wherein the processing the obtained data, reversely resolving the running mechanism according to the data driven algorithm, and building a data model driven high-performance virtual simulation model specifically comprises:
performing data processing on one or more of sensor data, mechanism simulation data, and fusion data to obtain data processing result, selecting a regression algorithm, training the regression algorithm based on the data processing result, and building the data model driven high-performance virtual simulation model.

6. The DT data model driven high-performance virtual simulation method according to claim 5, wherein the data model driven high-performance virtual simulation model is a data regression black box model built through the regression algorithm with the product design condition of variable operating conditions or variable product structures as input and performance characterization data as output, and the regression algorithm comprises CNN, ANN, and SVM.

7. The DT data model driven high-performance virtual simulation method according to claim 1, wherein the sensor data, the mechanism simulation data, the fusion data, and the virtual simulation results are all multi-type multi-index and multi-dimension data, and the data model driven high-performance virtual simulation model built for constant operating conditions or design product is multifunctional.

8. A DT data model driven high-performance virtual simulation system, comprising:
a data obtaining module, configured to: based on a product design process, pay attention to variable operating conditions or variable product structure conditions to obtain three kinds of data relevant to a design product, relevant products, or operating conditions: sensor data, mechanism simulation data, and fusion data obtained by correcting the mechanism simulation data with the sensor data;
a model building module, configured to: process the obtained data, reversely resolve running mechanism according to the data driven algorithm, and build a data model driven high-performance virtual simulation model;
a virtual simulation result obtaining module, configured to: based on new operating conditions of the design product or improved new products, call the built data model driven high-performance virtual simulation model to obtain virtual simulation results; and
a feedback guidance module, configured to: analyze performance of the design product under new operating conditions or new products according to the virtual simulation results to provide feedback guidance for product design.

9. A computer-readable storage medium, storing a program, wherein the program implements the steps of the DT data model driven high-performance virtual simulation method according to claim 1 when being executed by a processor.

10. An electronic device, comprising a memory, a processor, and a program stored on the memory and capable of running on the processor, the processor implementing the steps of the DT data model driven high-performance virtual simulation method according to claim 1 when executing the program.
